(19) United States
(12) Patent Application Publication
(10) Pub. No.: US 2023/0121505 A1
(43) Pub. Date: Apr. 20, 2023

(54) ELECTRONIC DEVICE, ELECTRONIC ELEMENT SOLDERING METHOD AND LIGHT-EMITTING DIODE DISPLAY MANUFACTURING METHOD

(71) Applicant: Skiileux Electricity Inc., Taoyuan City (TW)

(72) Inventors: Chien-Shou LIAO, Taoyuan City (TW); Chih-Cheng WANG, Taoyuan City (TW); Te Fu CHANG, Taoyuan City (TW)

(21) Appl. No.: 17/818,005

(22) Filed: Aug. 8, 2022

Related U.S. Application Data
(60) Provisional application No. 63/255,442, filed on Oct. 14, 2021.

(30) Foreign Application Priority Data
Jun. 29, 2022 (TW) 111124330

(51) Int. Cl. H01L 33/00; H01L 33/06

(52) U.S. Cl. CPC H01L 33/0095; H01L 33/0008; H01L 33/06; H01L 2933/0016

(57) ABSTRACT

An electronic element soldering method includes providing a substrate, wherein the substrate has a to-be-soldered position, placing an electronic device including an electronic element, a heating element, and a parallel-connected circuit on the to-be-soldered position of the substrate, adding a solder between the electronic element of the electronic device and the to-be-soldered position of the substrate, applying a heating current into the parallel-connected circuit of the electronic device to allow the heating element of the parallel-connected circuit to generate a thermal energy for melting the solder, thereby securing the electronic element on the to-be-soldered position of the substrate via the solder that is melted, applying a breaking current that is larger than the heating current into the parallel-connected circuit to allow an open to occur in a parallel branch corresponding to the heating element of the parallel-connected circuit, and stopping the breaking current.

### RELATED APPLICATIONS

This application claims priority to U.S. Provisional Application Ser. No. 63/255,442, filed Oct. 14, 2021, and Taiwan Application Serial Number 111124330, filed Jun. 29, 2022, which are herein incorporated by reference.

### BACKGROUND

### Technical Field

The present disclosure relates to an electronic device, an electronic element soldering method and a light-emitting diode (LED) display manufacturing method. More particularly, the present disclosure relates to an electronic device, an electronic element soldering method and a light-emitting diode (LED) display manufacturing method which are heated by powering.

### Description of Related Art

Generally, electronic elements like LED include electrodes corresponding to the metal points of the circuit board, and can be mounted thereto by soldering. A conventional soldering method is reflow soldering, a reflow oven can be used to heat the solder on the circuit board, and then the melted solder can be used to connect the electronic element and the circuit board. However, the reflow oven causes bending and deformation of the circuit board easily, a quality standard of the material of the circuit board is high in such soldering method, and disadvantages exist therein.

Some circuit boards are designed with heating elements and heating metals. The heating metals are electrically connected to the heating elements and correspond to the metal points. Through the heating elements to provide power for the heating metals, the heating metals can generate a thermal energy to melt the solder. Nevertheless, a multi-layer substrate is required owing to the need of installing the heating elements and the heating metals in the circuit board, and the manufacturing process thereof is complex and the cost is high.

Hence, how to improve the soldering method and the structure for mounting the electronic element on the circuit board becomes a pursued target for practitioners.

### SUMMARY

According to an aspect of the present disclosure, an electronic device includes an electronic element, a heating element disposed at the electronic element, and a parallel-connected circuit connecting the electronic element and the heating element in parallel.

According to another aspect of the present disclosure, an electronic element soldering method includes providing a substrate, wherein the substrate has a to-be-soldered position, placing the aforementioned electronic device on the to-be-soldered position of the substrate, adding a solder between the electronic element of the electronic device and the to-be-soldered position of the substrate, applying a heating current into the parallel-connected circuit of the electronic device to allow the heating element of the parallel-connected circuit to generate a thermal energy for melting the solder, thereby securing the electronic element on the to-be-soldered position of the substrate via the solder that is melted, applying a breaking current that is larger than the heating current into the parallel-connected circuit to allow an open to occur in a parallel branch corresponding to the heating element of the parallel-connected circuit, and stopping the breaking current.

According to still another aspect of the present disclosure, a light-emitting diode display manufacturing method includes the aforementioned electronic element soldering method to solder light-emitting diodes (LEDs).

According to yet another aspect of the present disclosure, an electronic element soldering method includes providing a substrate, wherein the substrate has a to-be-soldered position, a heating element is correspondingly disposed on the to-be-soldered position of the substrate, placing an electronic element on the to-be-soldered position of the substrate to allow the electronic element and the heating element to be connected in parallel to form a parallel-connected circuit, adding a solder between the electronic element and the to-be-soldered position of the substrate, applying a heating current into the parallel-connected circuit to allow the heating element of the parallel-connected circuit to generate a thermal energy for melting the solder, thereby securing the electronic element on the to-be-soldered position of the substrate via the solder that is melted, applying a breaking current that is larger than the heating current into the parallel-connected circuit to allow an open to occur in a parallel branch corresponding to the heating element of the parallel-connected circuit, and stopping the breaking current.

According to still yet another aspect of the present disclosure, a light-emitting diode display manufacturing method includes the aforementioned electronic element soldering method to solder light-emitting diodes (LEDs).

### BRIEF DESCRIPTION OF THE DRAWINGS

The disclosure can be more fully understood by reading the following detailed description of the embodiments, with reference made to the accompanying drawings as follows:

FIG. 1 shows a schematic view of an electronic device according to a first embodiment of the present disclosure.

FIG. 2 shows a top view of the heating element of the electronic device of FIG. 1.

FIG. 3 shows a soldering process of the electronic device of FIG. 1 soldered on a substrate.

FIG. 4 shows an equivalent circuit of the electronic device of FIG. 1 during the soldering process.

FIG. 5 shows a current-time diagram of a heating current and a breaking current of the electronic device of FIG. 1.

FIG. 6 shows another equivalent circuit of the electronic device of FIG. 1 during the soldering process.

FIG. 7 shows a top view of a heating element of the electronic device according to a second embodiment of the present disclosure.

FIG. 8 shows a top view of a heating element of the electronic device according to a third embodiment of the present disclosure.

FIG. 9 shows a schematic view of an electronic element, a heating element, and a substrate according to a fourth embodiment of the present disclosure.

FIG. 10 shows a top view of the heating element and the substrate of FIG. 9.

FIG. 11 shows a block chart of an electronic element soldering method according to a fifth embodiment of the present disclosure.

FIG. 12 shows one flow chart of the electronic element soldering method of FIG. 11.

FIG. 13 shows another flow chart of the electronic element soldering method of FIG. 11.

### DETAILED DESCRIPTION

It will be understood that when an element (or mechanism or module) is referred to as being “disposed on”, “connected to” or “coupled to” another element, it can be directly disposed on, connected or coupled to the other element, or intervening elements may also be present. In contrast, when an element is referred to as being “directly disposed on”, “directly connected to” or “directly coupled to” another element, there are no intervening elements present.

In addition, the terms first, second, third, etc. are used herein to describe various elements or components, these elements or components should not be limited by these terms. Consequently, a first element or component discussed below could be termed a second element or component.

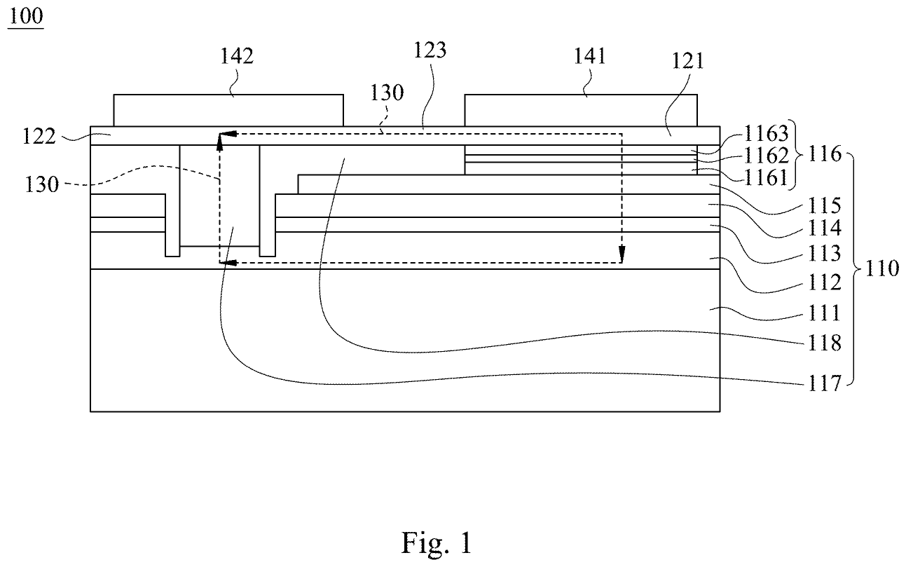

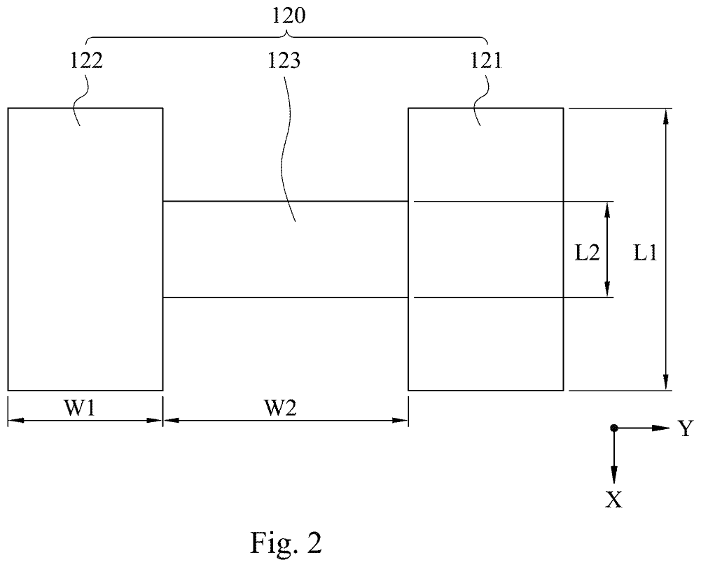

Please refer to FIGS. 1 and 2, the electronic device 100 includes an electronic element 110, a heating element 120 and a parallel-connected circuit 130. The heating element 120 is disposed on the electronic element 110, and the parallel-connected circuit 130 connects the electronic element 110 and the heating element 120 in parallel.

To be more specific, the electronic element 110 can be an LED and includes an element substrate 111, a first-type semiconductor layer 112, an active layer 113, a second-type semiconductor layer 114, an indium tin oxide (ITO) layer 115, a P electrode 116, an N electrode 117, and a protection layer 118. The element substrate 111 may be for example made of sapphire. The first-type semiconductor layer 112 may be N-type nitride semiconductor stack layers made by adding N-type dopants to GaN, AlGaN, AlInGaN or InGaN. The active layer 113 can be made of quantum wells, such as multiple quantum wells. The second-type semiconductor layer 114 may be P-type nitride semiconductor stack layers made by adding P-type dopants to GaN, AlGaN, AlInGaN or InGaN. The present disclosure is not limited thereto.

The P electrode 116 may have a multi-layer structure and includes a first titanium layer 1161, an aluminum layer 1162 and a second titanium layer 1163 in order. The N electrode 117 may have a multi-layer structure (not shown in the drawings) and consists of the same components as the P electrode 116. In other embodiments, the P electrode and the N electrode may have a singular-layer structure, and may consist of one metal.

The heating element 120 can be disposed on the electronic element 110 and includes a first connecting section 121, a second connecting section 122 and a heating section 123. The first connecting section 121 can be disposed on the P electrode 116 and is electrically connected thereto, the second connecting section 122 can be disposed on the N electrode 117 and is electrically connected thereto, and the heating section 123 can be connected between the first connecting section 121 and the second connecting section 122. The first connecting section 121, the second connecting section 122 and the heating section 123 can be all made of ITO, and thus the first connecting section 121, the second connecting section 122 and the heating section 123 are connected to form a current passage configured for a current to pass therethrough. In other embodiments, the heating element can be, but not limited to, zinc oxide, tungsten, tantalum nitride, or tantalum oxide.

Since the first connecting section 121, the second connecting section 122 and the heating section 123 of the heating element 120 are connected to form a current passage, and the P electrode 116, the indium tin oxide layer 115, the second-type semiconductor layer 114, the active layer 113, the first-type semiconductor layer 112 and the N electrode 117 can form another current passage, the two current passages (parallel branches) using the same two terminals can be deemed as the parallel-connected circuit 130.

In the first embodiment, a first tin protrusion 141 and a second tin protrusion 142 can be formed as manufacturing the electronic element 110 and the heating element 120. In other words, the electronic element 110, the heating element 120, the first tin protrusion 141, and the second tin protrusion 142 can be made integrally.

As shown in FIG. 2, a width W1 of each of the first connecting section 121 and the second connecting section 122 in a Y-axis is shorter than a width W2 of the heating section 123 in the Y-axis, and a length L1 of each of the first connecting section 121 and the second connecting section 122 in an X-axis is longer than a length L2 of the heating section 123 in the X-axis.

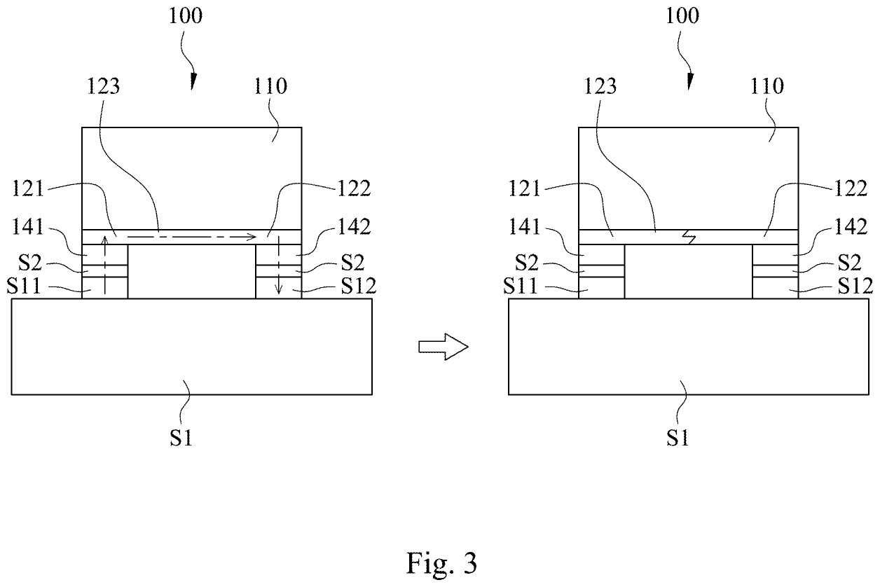

Please refer to FIGS. 3 to 5 with references of FIGS. 1 to 2, the electronic device 100 can be placed on a substrate S1. The substrate S1 includes a first substrate soldered point S11 and a second substrate soldered point S12. The first substrate soldered point S11 is configured to be electrically connected to the P electrode 116 of the electronic device 100, and the second substrate soldered point S12 is configured to be electrically connected to the N electrode 117 of the electronic device 100. Hence, the driving circuit of the substrate S1 can turn on or turn off the electronic element 110. The substrate S1 can be a thin-film transistor (TFT) substrate. In other embodiments, the substrate can be other circuit boards including active elements, but the present disclosure is not limited thereto.

As shown in FIGS. 3 to 5, a solder S2 can be added between the first substrate soldered point S11 and the first tin protrusion 141, and another solder S2 can be added between the second substrate soldered point S12 and the second tin protrusion 142. In the beginning, as feeding a heating current I1, the forward voltage is higher than the initial voltage of the electronic element 110, a portion of the heating current I1 flows into the current passage of the parallel-connected circuit 130 formed by the first substrate soldered point S11, the first tin protrusion 141, the P electrode 116, the indium tin oxide layer 115, the second-type semiconductor layer 114, the active layer 113, the first-type semiconductor layer 112, the N electrode 117, the second tin protrusion 142 and the second substrate soldered point S12, and another portion of the heating current I1 flows into the current passage of the parallel-connected circuit 130 formed by the first substrate soldered point S11, the first tin protrusion 141, the first connecting section 121, the heating section 123, the second connecting section 122, the second tin protrusion 142 and the second substrate soldered point S12. The heating current I1 has the same flowing direction with the forward current. The heating current I1 is proximate 30 mA and continues for 20 ms. Therefore, the temperature of the heating section 123 rises to about 260° C. to melt the first tin protrusion 141, the solders S2 and the second tin protrusion 142, thereby completing the soldering process between the electronic element 110 and the substrate S1. In other embodiments, as feeding the heating current in the beginning, the forward voltage can be lower than the initial voltage of the electronic element, no current can flow into the current passage of the parallel-connected circuit formed by the first substrate soldered point, the first tin protrusion, the P electrode, the indium tin oxide layer, the second-type semiconductor layer, the active layer, the first-type semiconductor layer, the N electrode, the second tin protrusion and the second substrate soldered point, and all of the heating current can flow into the heating element. In other embodiments, the first tin protrusion and the second tin protrusion can be used as solders, and no extra solder is required.

Subsequently, the current is enlarged, that is, feeding a breaking current I2, which is about 200 mA and continues for 1 ms. Hence, the temperature of the heating section 123 rises to about 400° C., and a crack is generated thereon. As a result, no more current is allowed to pass through the current passage of the parallel-connected circuit 130 formed by the first connecting section 121, the heating section 123, and the second connecting section 122.

In other words, according to the first embodiment, the temperature is raised in two steps by adjusting the current. In the first step, the solders S2 can be melted by raising the temperature, and, in the second step, the current passage of the parallel-connected circuit 130 formed by the first connecting section 121, the heating section 123, and the second connecting section 122 is opened by further raising the temperature. Therefore, the original first substrate soldered point S11, the second substrate soldered point S12 and the driving circuit of the substrate S1 can be used directly to achieve soldering, no extra heating element is required.

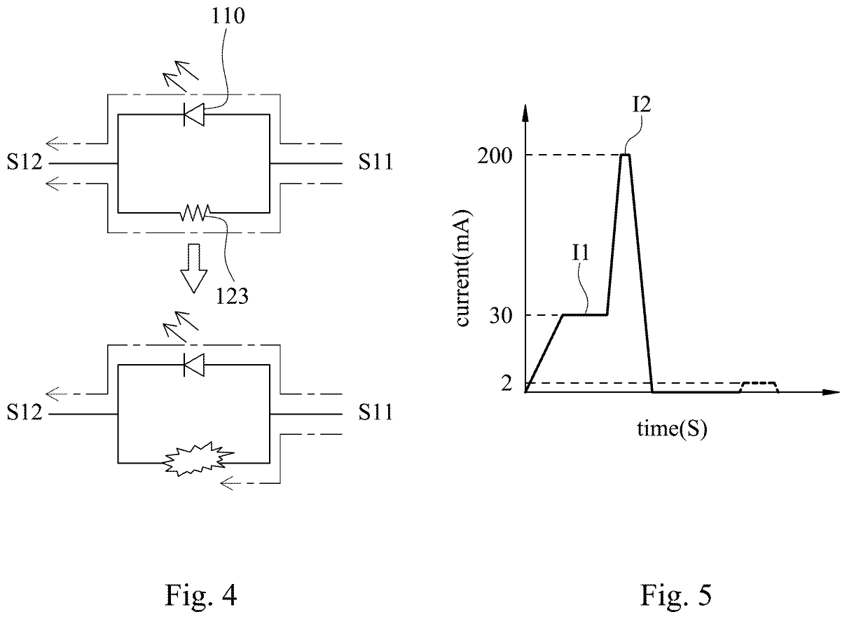

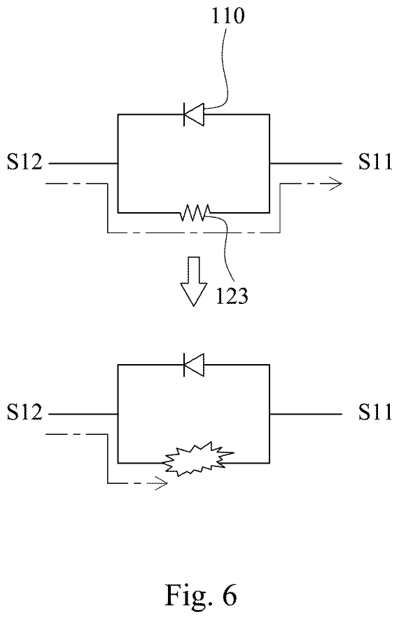

Please refer to FIG. 6 with references of FIGS. 1 to 3, in addition to feed the forward current relative to the electronic element 110 into the parallel-connected circuit 130 as FIG. 4, a reverse current relative to the electronic element 110, flowing into the second substrate soldered point S12 and the second tin protrusion 142 and then flowing out from the first tin protrusion 141 and the first substrate soldered point S11, can be fed into the parallel-connected circuit 130 as FIG. 6, and, during soldering, a reverse voltage can be, but not limited to, given to the substrate S1.

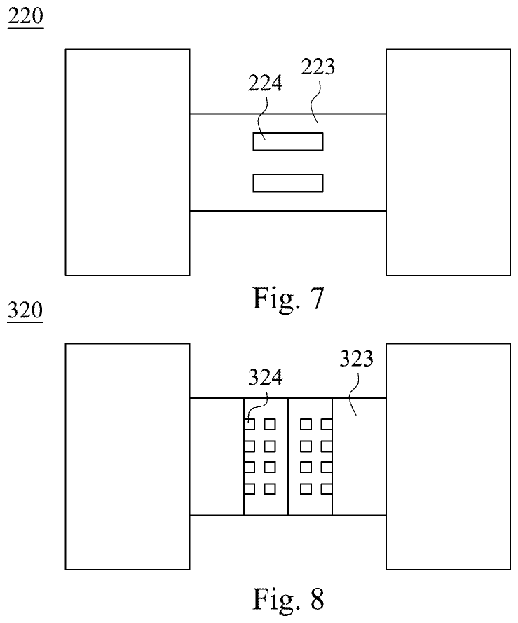

Please refer to FIG. 7, the structure and the soldering process of the electronic device in the second embodiment are similar to the first embodiment, but the difference is that the heating element 220 can include two hollow portions 224 located on the heating section 223. Each hollow portion 224 is rectangular, and a resistance of the heating element 220 is 55.8Ω, which is different from the resistance of the heating element 120.

Please refer to FIG. 8, the structure and the soldering process of the electronic device in the third embodiment are similar to the first embodiment, but the difference is that the heating element 320 can include a plurality of hollow portions 324 located on the heating section 323. Each hollow portion 324 is square-shaped, and a resistance of the heating element 320 is 44Ω, which is different from the resistance of the heating element 120 and is also different from the resistance of the heating element 220. In other embodiments, the required resistance of the heating element can be designed by modifying the structural configuration thereof, and the present disclosure is not limited thereto.

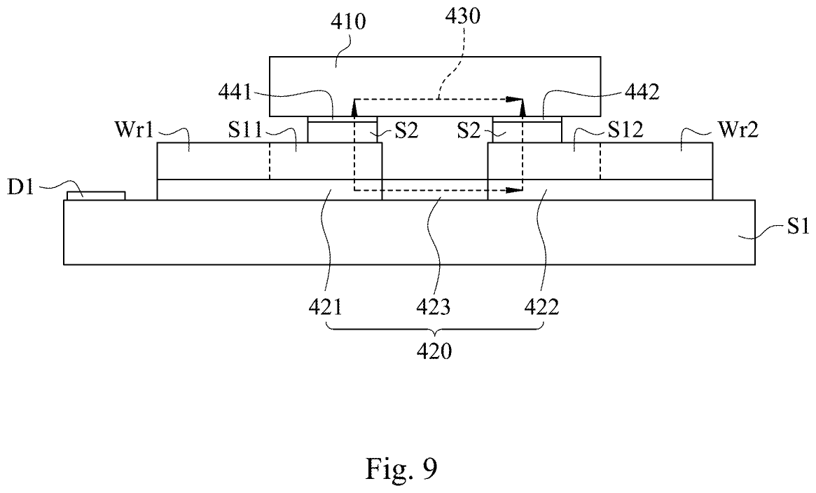

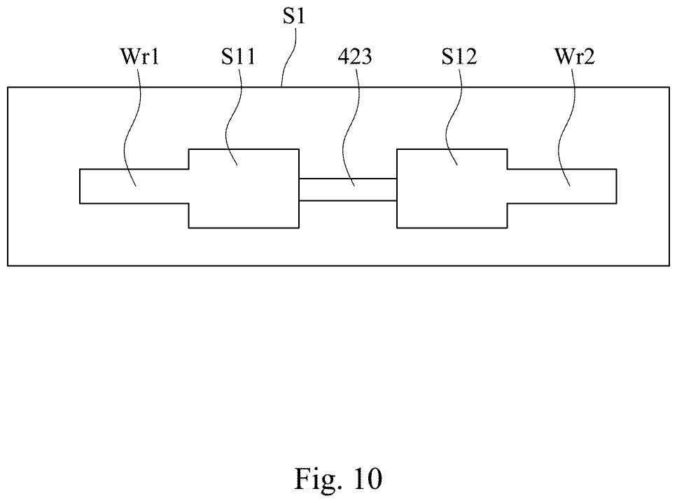

Please refer to FIGS. 9 and 10, the heating element 420 and the electronic element 410 are disposed on the substrate S1.

Specifically, the electronic element 410 can be an LED and includes an element substrate, a first-type semiconductor layer, an active layer, a second semiconductor layer, an indium tin oxide layer, a P electrode, and an N electrode. A first tin protrusion 441 and a second tin protrusion 442 can be connected to the P electrode and the N electrode, respectively. The difference between the fourth embodiment and the first embodiment is that the heating element 420 is disposed on the substrate S1, but not on the electronic element 410 and being integrally formed with the electronic element 410. More specifically, the heating element 420 can include a first connecting section 421, a second connecting section 422 and a heating section 423. The first connecting section 421 is located between the surface of the substrate S1 and the first substrate soldered point S11, the second connecting section 422 is located between the surface of the substrate S1 and the second substrate soldered point S12, and the heating section 423 is located on the surface of the substrate S1 and connected to the first connecting section 421 and the second connecting section 422. The first connecting section 421, the second connecting section 422 and the heating section 423 can be all made of ITO, thereby allowing the first connecting section 421, the second connecting section 422 and the heating section 423 to be connected to form a current passage. Since the first substrate soldered point S11 corresponds to the P electrode, and the second substrate soldered point S12 corresponds to the N electrode, the aforementioned current passage and another current passage formed by the P electrode, the indium tin oxide layer, the second-type semiconductor layer, the active layer, the first-type semiconductor layer and the N electrode can be assembled to form a parallel-connected circuit 430.

As shown in FIGS. 9 and 10, a wire Wr1 can be connected to the first substrate soldered point S11, another wire Wr2 can be connected to the second substrate soldered point S12, and can be powered by the LED driver D1. Because the shapes of the first connecting section 421 and the second connecting section 422 are the same as the shapes of the first substrate soldered point S11 and the second substrate soldered point S12, the first connecting section 421 and the second connecting section 422 are not shown in the top view of FIG. 10. Hence, during soldering, the LED driver D1 can be controlled to feed the heating current first, and the heating current can flow into the first connecting section 421, the heating section 423 and the second connecting section 422 to melt the solders S2. Subsequently, the breaking current can be fed, and the heating section 423 cracks to open the current passage of parallel-connected circuit 430 formed by the first connecting section 421, the heating section 423 and the second connecting section 422. In other embodiments, the first tin protrusion and the second tin protrusion disposed on the electronic element can be used as solders, and no extra solder is required.

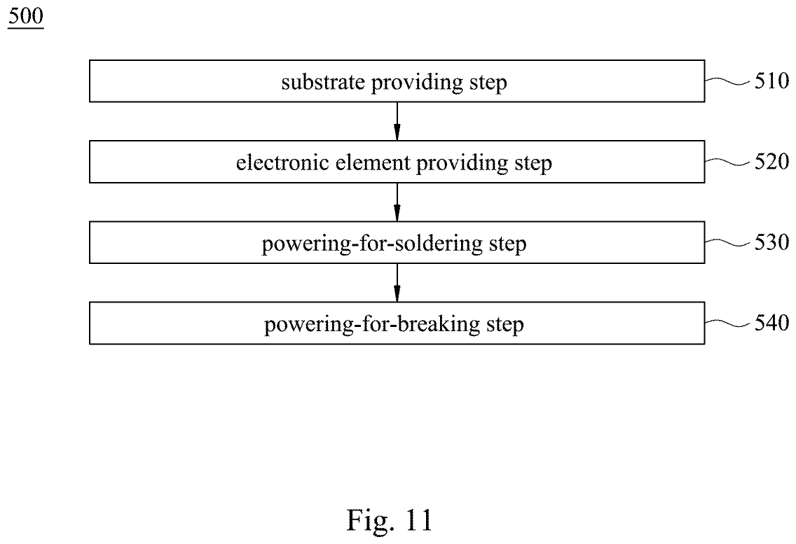

Please refer to FIG. 11, the electronic element soldering method 500 includes a substrate providing step 510, an electronic element providing step 520, a powering-for-soldering step 530 and a powering-for-breaking step 540.

In the substrate providing step 510, a substrate is provided, and the substrate includes a first substrate soldered point and a second substrate soldered point.

In the electronic element providing step 520, an electronic element is provided, and the electronic element includes a first element soldered point and a second element soldered point. The first element soldered point can contact the first substrate soldered point via a solder, and the second element soldered point can contact the second substrate soldered point via another solder.

In the powering-for-soldering step 530, a first current can be fed to a conductive heating structure via the first substrate soldered point and the second substrate soldered point, and the conductive heating structure can be positioned on the electronic element to form a current passage between the first element soldered point and the second element soldered point, or be positioned on the substrate to form a current passage between the first substrate soldered point and the second substrate soldered point. The first current can pass the current passage to allow the conductive heating structure to generate a thermal energy to melt the aforementioned solder to connect the first substrate soldered point and the first element soldered point, and to melt the aforementioned another solder to connect the second substrate soldered point and the second element soldered point.

In the powering-for-breaking step 540, a second current can be fed to the conductive heating structure via the first substrate soldered point and the second substrate soldered point to open the current passage.

For the first embodiment of FIG. 1, the first tin protrusion 141 can be defined as the first element soldered point, the second tin protrusion 142 can be defined as the second element soldered point, and the heating element 120 can be defined as the conductive heating structure located on the electronic element 110. If the first tin protrusion 141 and the second tin protrusion 142 are used as solders, the P electrode 116 can be defined as the first element soldered point, and the N electrode 117 can be defined as the second element soldered point. Moreover, for the fourth embodiment of FIG. 9, the heating element 420 can be defined as the conductive heating structure located on the substrate S1. Hence, the first current can be fed to the conductive heating structure directly via the first substrate soldered point and the second substrate soldered point, and the conductive heating structure can generate a thermal energy after powered to melt the solders. After that, the current is enlarged, and the heating section cracks to open the current passage. During powering, the LED driver can be controlled to generate a heating current between the first substrate soldered point and the second substrate soldered point, and a portion thereof flowing into the conductive heating structure can be defined as the first current. In an embodiment, the heating current can totally flow into the conductive heating structure and is equal to the first current, but the present disclosure is not limited thereto. Similarly, the LED driver can be controlled to generate a breaking current between the first substrate soldered point and the second substrate soldered point, and a portion thereof flowing into the conductive heating structure can be defined as the second current. Because the heating current is smaller than the breaking current, the first current can be smaller than the second current.

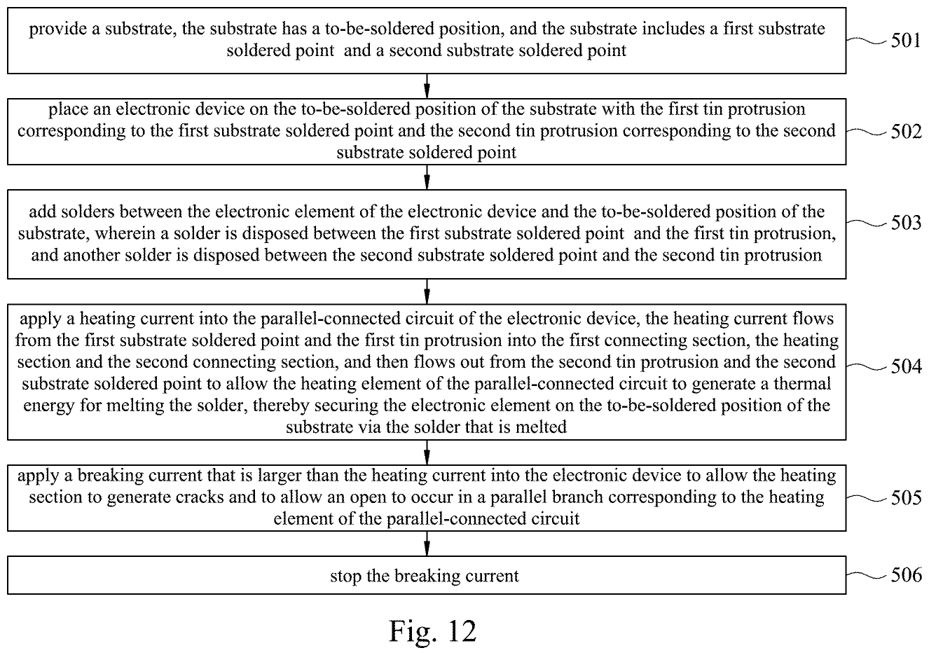

Please refer to FIG. 12, in an embodiment, step 501 can be executed to provide a substrate, and the substrate has a to-be-soldered position. As shown in FIG. 3, the substrate S1 can include a first substrate soldered point S11 and a second substrate soldered point S12.

Step 502 can be executed to place an electronic device on the to-be-soldered position of the substrate. As shown in FIGS. 1 and 3, the electronic device 100 can be put on the substrate S1 with the first tin protrusion 141 corresponding to the first substrate soldered point S11 and the second tin protrusion 142 corresponding to the second substrate soldered point S12.

Step 503 can be executed to add solders between the electronic element of the electronic device and the to-be-soldered position of the substrate. As shown in FIG. 3, a solder S2 can be disposed between the first substrate soldered point S11 and the first tin protrusion 141, and another solder S2 can be disposed between the second substrate soldered point S12 and the second tin protrusion 142. In other embodiments, the solders can be applied to the P electrode and the N electrode on the electronic element, respectively, that is, using the first tin protrusion and the second tin protrusion as the solders, and no extra solder is required.

Step 504 is executed to apply a heating current into the parallel-connected circuit of the electronic device to allow the heating element of the parallel-connected circuit to generate a thermal energy for melting the solder, thereby securing the electronic element on the to-be-soldered position of the substrate via the solder that is melted. The heating current can be a forward current relative to the electronic element of the parallel-connected circuit. As shown in FIGS. 3 to 5, the heating current I1 can flow from the first substrate soldered point S11 and the first tin protrusion 141 into the first connecting section 121, the heating section 123 and the second connecting section 122, and then flows out from the second tin protrusion 142 and the second substrate soldered point S12 (the current passing the aforementioned elements being deemed as the first current). Consequently, the temperature of the heating section 123 rises by powering, and the first tin protrusion 141, the solders S2 and the second tin protrusion 142 are melted to mount the electronic element 110 on the substrate S1. In other embodiments, the heating current is a reverse current relative to the electronic element of the parallel-connected circuit.

Subsequently, step 505 can be executed to apply a breaking current that is larger than the heating current into the electronic device to allow an open to occur in a parallel branch corresponding to the heating element of the parallel-connected circuit, and the breaking current is a forward current relative to the electronic element of the parallel-connected circuit. As shown FIGS. 3 to 5, after the solders S2 are melted and the soldering process is completed, the current passage formed by the first connecting section 121, the second connecting section 122 and the heating section 123 is not needed. Hence, the breaking current I2, 200 mA, can be fed therein, and all of the breaking current I2 or at least a portion of the breaking current I2 (the current passing the first connecting section 121, the heating section 123 and the second connecting section 122 being deemed as the second current) flows into the heating section 123 to allow the heating section 123 to generate cracks. Therefore, the current passage formed by the first connecting section 121, the second connecting section 122 and the heating section 123 is opened, and the first connecting section 121 and the second connecting section 122 cannot electrically connect to each other via the heating section 123. Finally, step 506 can be executed to stop the breaking current. Please be noted that, in the document, the method of feeding the breaking current after stopping the heating current and the method of enlarging the heating current to become the breaking current while not stopping the heating current are both included.

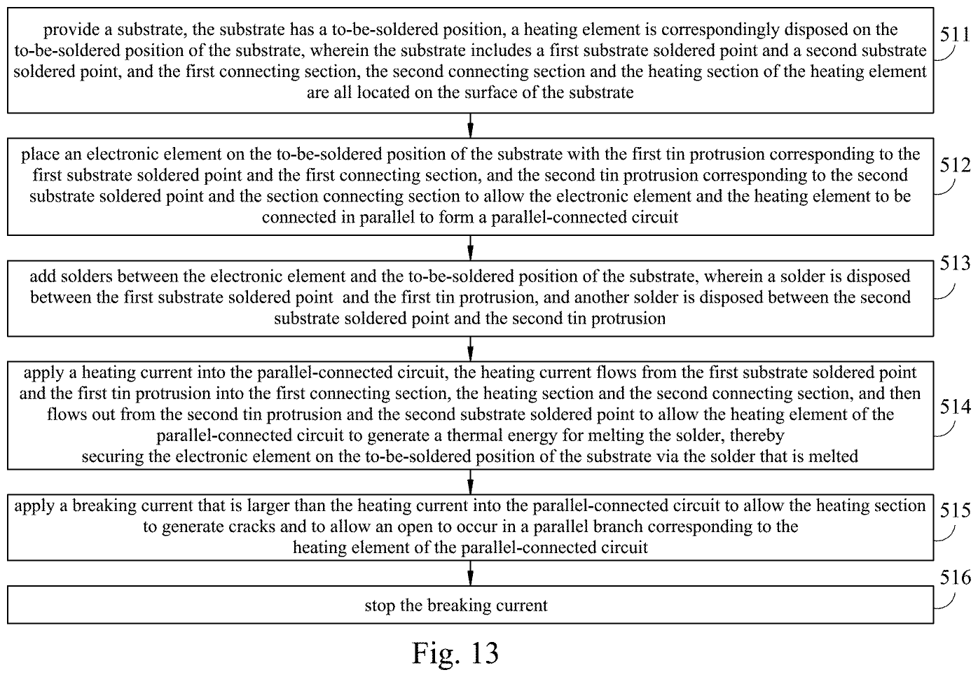

Please refer to FIG. 13, in another embodiment, step S11 can be executed to provide a substrate, the substrate has a to-be-soldered position, and a heating element is correspondingly disposed on the to-be-soldered position of the substrate. As shown in FIG. 9, the substrate S1 can include a first substrate soldered point S11 and a second substrate soldered point S12, and the first connecting section 421, the second connecting section 422 and the heating section 423 are all located on the surface of the substrate S1.

Step S12 can be executed to place an electronic element on the to-be-soldered position of the substrate to allow the electronic element and the heating element to be connected in parallel to form a parallel-connected circuit. As shown in FIG. 9, the electronic element 410 can be placed on the substrate S1 with the first tin protrusion 441 corresponding to the first substrate soldered point S11 and the first connecting section 421, and the second tin protrusion 442 corresponding to the second substrate soldered point S12 and the second connecting section 422, thereby forming the parallel-connected circuit 430.

Step 513 can be executed to add a solder between the electronic element and the to-be-soldered position of the substrate. As shown in FIG. 9, a solder S2 can be disposed between the first substrate soldered point S11 and the first tin protrusion 441, and another solder S2 can be disposed between the second substrate soldered point S12 and the second tin protrusion 442. In other embodiments, the solder can be applied to the P electrode and the N electrode on the electronic element, respectively, that is, using the first tin protrusion and the second tin protrusion as the solders, and no extra solder is required.

Step 514 is executed to apply a heating current into the parallel-connected circuit to allow the heating element of the parallel-connected circuit to generate a thermal energy for melting the solder, thereby securing the electronic element on the to-be-soldered position of the substrate via the solder that is melted. The heating current can be a forward current relative to the electronic element of the parallel-connected circuit. As shown in FIG. 9, the heating current I1 can flow from the first substrate soldered point S11 and the first tin protrusion 441 into the first connecting section 421, the heating section 423 and the second connecting section 422, and then flows out from the second tin protrusion 442 and the second substrate soldered point S12 (the current passing the aforementioned elements being deemed as the first current). Consequently, the temperature of the heating section 423 rises by powering, and the first tin protrusion 441, the solders S2 and the second tin protrusion 442 are melted to mount the electronic element 410 on the substrate S1. In other embodiments, a reverse current can be fed.

Subsequently, step 515 can be executed to apply a breaking current that is larger than the heating current into the parallel-connected circuit to allow an open to occur in a parallel branch corresponding to the heating element of the parallel-connected circuit. As shown FIG. 9, after the solders S2 are melted and the soldering process is completed, the current passage formed by the first connecting section 421, the second connecting section 422 and the heating section 423 is not needed. Hence, the breaking current I2, 200 mA, can be fed, and all of the breaking current I2 or at least a portion of the breaking current I2 (the current passing the first connecting section 421, the heating section 423 and the second connecting section 422 being deemed as the second current) flows into the heating section 423 to allow the heating section 423 to generate cracks. Therefore, the current passage formed by the first connecting section 421, the second connecting section 422 and the heating section 423 is opened, and the first connecting section 421 and the second connecting section 422 cannot electrically connect to each other via the heating section 423. Finally, step 516 can be executed to stop the breaking current.

The present disclosure can further include a light-emitting diode display manufacturing method, which includes the electronic element soldering method 500 shown in FIGS. 11 to 13 to solder light-emitting diodes (LEDs).

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. An electronic device, comprising:
an electronic element;
a heating element disposed at the electronic element; and
a parallel-connected circuit connecting the electronic element and the heating element in parallel.

2. The electronic device of claim 1, wherein a material of the heating element is indium tin oxide, zinc oxide, tungsten, tantalum nitride, or tantalum oxide.

3. The electronic device of claim 1, wherein the electronic element is a light-emitting diode (LED).

4. An electronic element soldering method, comprising:
providing a substrate, wherein the substrate has a to-be-soldered position;
placing the electronic device of claim 1 on the to-be-soldered position of the substrate;
adding a solder between the electronic element of the electronic device and the to-be-soldered position of the substrate;
applying a heating current into the parallel-connected circuit of the electronic device to allow the heating element of the parallel-connected circuit to generate a thermal energy for melting the solder, thereby securing the electronic element on the to-be-soldered position of the substrate via the solder that is melted;
applying a breaking current that is larger than the heating current into the parallel-connected circuit to allow an open to occur in a parallel branch corresponding to the heating element of the parallel-connected circuit; and
stopping the breaking current.

5. The electronic element soldering method of claim 4, wherein the heating current is a forward current relative to the electronic element of the parallel-connected circuit.

6. The electronic element soldering method of claim 4, wherein the heating current is a reverse current relative to the electronic element of the parallel-connected circuit.

7. The electronic element soldering method of claim 4, wherein the breaking current is a forward current relative to the electronic element of the parallel-connected circuit.

8. The electronic element soldering method of claim 4, wherein the breaking current is a reverse current relative to the electronic element of the parallel-connected circuit.

9. The electronic element soldering method of claim 4, wherein the substrate is a thin-film transistor (TFT) substrate.

10. The electronic element soldering method of claim 4, wherein the electronic element is a light-emitting diode (LED).

11. The electronic element soldering method of claim 10, wherein the solder is added to a P electrode and an N electrode of the light-emitting diode (LED).

12. A light-emitting diode display manufacturing method, comprising the electronic element soldering method of claim 10 to solder light-emitting diodes (LEDs).

13. An electronic element soldering method, comprising:
providing a substrate, wherein the substrate has a to-be-soldered position, a heating element is correspondingly disposed on the to-be-soldered position of the substrate;
placing an electronic element on the to-be-soldered position of the substrate to allow the electronic element and the heating element to be connected in parallel to form a parallel-connected circuit;
adding a solder between the electronic element and the to-be-soldered position of the substrate;
applying a heating current into the parallel-connected circuit to allow the heating element of the parallel-connected circuit to generate a thermal energy for melting the solder, thereby securing the electronic element on the to-be-soldered position of the substrate via the solder that is melted;
applying a breaking current that is larger than the heating current into the parallel-connected circuit to allow an open to occur in a parallel branch corresponding to the heating element of the parallel-connected circuit; and
stopping the breaking current.

14. The electronic element soldering method of claim 13, wherein the heating current is a forward current relative to the electronic element of the parallel-connected circuit.

15. The electronic element soldering method of claim 13, wherein the heating current is a reverse current relative to the electronic element of the parallel-connected circuit.

16. The electronic element soldering method of claim 13, wherein the breaking current is a forward current relative to the electronic element of the parallel-connected circuit.

17. The electronic element soldering method of claim 13, wherein the breaking current is a reverse current relative to the electronic element of the parallel-connected circuit.

18. The electronic element soldering method of claim 13, wherein the substrate is a thin-film transistor (TFT) substrate.

19. The electronic element soldering method of claim 13, wherein the electronic element is a light-emitting diode (LED).

20. The electronic element soldering method of claim 19, wherein the solder is added to a P electrode and an N electrode of the light-emitting diode (LED).

21. A light-emitting diode display manufacturing method, comprising the electronic element soldering method of claim 19 to solder light-emitting diodes (LEDs).
